(19) United States
(12) Patent Application Publication
(10) Pub. No.: US 2014/0261673 A1
(43) Pub. Date: Sep. 18, 2014

(54) TUNING THE ANTI-REFLECTIVE, ABRASION RESISTANCE, ANTI-SOILING AND SELF-CLEANING PROPERTIES OF TRANSPARENT COATINGS FOR DIFFERENT GLASS SUBSTRATES AND SOLAR CELLS

(71) Applicant: Enki Technology, Inc., San Jose, CA (US)

(72) Inventors: Vinod Nair, San Jose, CA (US); Bakul Champaklal Dave, Carbondale, IL (US)

(73) Assignee: Enki Technology, Inc., San Jose, CA (US)

(21) Appl. No.: 14/212,167

(22) Filed: Mar. 14, 2014

Related U.S. Application Data
(60) Provisional application No. 61/794,735, filed on Mar. 15, 2013.

(51) Int. Cl. H01L 31/0216

(52) U.S. Cl. CPC H01L 31/02168
USPC 136/256; 106/287.14; 106/14.41

(57) ABSTRACT

Coating compositions disclosed herein include silane-based precursors that are used to form coatings through a sol-gel process including a hydrolyzed organosilane-based sol and a hydrolyzed tetraalkoxysilane-based sol. The coatings are characterized by anti-reflective, abrasion resistant, and anti-soiling properties and the tunability of those properties with respect to different glass substrates, solar cells or geographic locations of the solar panels. The coatings formed from the compositions described herein have wide application, including, for example, use as abrasion resistant coatings on the outer glass of solar cells, wherein the coating adheres through siloxane linkages. In some embodiments, when applied to glass and cured at a temperature of less than 300° C., the dried sol gel has abrasion resistance sufficient to pass standard EN-1096-2 with a loss of transmission of no more than 0.5% and enables a post-test light transmission gain of greater than 1% as compared to uncoated glass.

### CROSS-REFERENCE TO RELATED APPLICATIONS

This application claims the benefit of the following provisional application, which is hereby incorporated by reference in its entirety: U.S. Application No. 61/794,735, filed Mar. 15, 2013 (ENKI-0004-P01).

### STATEMENT REGARDING FEDERALLY SPONSORED RESEARCH OR DEVELOPMENT

This invention was made with government support under Contract DE-EE0006040 awarded by the U.S. Department of Energy. The government has certain rights in the invention.

### BACKGROUND

1. Field

The embodiments of the disclosure are directed to coatings and their uses. More particularly, the embodiments of the disclosure are directed to coating compositions that include silane-based precursors that are used to form coatings through a sol-gel process. The resulting coatings are characterized by anti-reflective, abrasion resistant, and anti-soiling properties and the tunability of those properties. The coatings also have extended weatherability to heat and humidity and protection against ambient corrosives. The coatings formed from the compositions described herein have wide application, including, for example, use as coatings on the outer glass of solar cells or panels.

2. Description of Related Art

This disclosure is related to the disclosure in U.S. application Ser. No. 12/769,580, filed Apr. 28, 2010 and U.S. application Ser. No. 13/184,568, filed Jul. 18, 2011.

Anti-reflective coatings are used in a wide variety of commercial applications ranging from sunglasses, windows, car windshields, camera lenses, solar panels, and architectural systems. These coatings minimize the reflections on the surface of the glass as the light rays travel through a discontinuous dielectric gradient. The reflection of light usually results in reduced transmittance of the light across the transparent material. For optical applications, it is important that a majority of incident light passes through the interface for maximum efficiency. In this context, anti-reflective coatings provide a useful benefit in optical applications.

Anti-reflective coatings are normally used in glasses, acrylics, and other transparent materials that serve as windows and glass panels associated with architectural structures or energy generating and saving systems. In building windows, they are used to maximize influx of incident light to maintain proper lighting or natural ambience as well as to minimize distracting reflections from glass surfaces.

In energy generating and saving devices, such as solar panels and light collectors, the utility of anti-reflective coatings lies in the enhanced efficiency of these devices due to a greater degree of light transmittance and, therefore, increased energy generation for the additional cost of the antireflective coating. Solar panels are warranted to provide energy for a period of 20-30 years. Therefore it is the expectation of the solar panel manufacturers using antireflective coatings on solar panels for increases in efficiency that the antireflective coatings will retain their antireflective properties for the same time period. The majority of the research in antireflective coatings for solar panels have been focused on maximizing the porosity of a film comprising SiO₂ so that the anti-reflective property is maximized. While maximizing the porosity of the SiO₂ anti-reflective coating increases the anti-reflective property of the coated film, it is also coincidentally designed to provide its best performance when the film is applied to the substrate. After the coating manufacturing process, the pores are likely to get filled by contaminants inside the factory causing the refractive index to increase. Furthermore, a predominantly porous anti-reflective SiO₂ coating will have a relatively lower resistance to abrasion than a non-porous or less porous anti-reflective SiO₂ coating.

In order for optical elements to perform optimally, it is necessary that they be free from surface contamination and depositions (e.g., dirt) that may reduce light transmittance and, therefore, performance of the coatings. In particular, for optical elements that are exposed to an outside environment, such as solar panels and building windows, the long term exposure to chemical and physical elements in the environment usually results in deposition of dirt on the surface of the optical element. The dirt may comprise particles of sand, soil, soot, clay, geological mineral particulates, air-borne aerosols, and organic particles such as pollen, cellular debris, biological and plant-based particulate waste matter, and particulate condensates present in the air. Over time, deposition of such dirt significantly reduces the optical transparency of the optical element. As a result, there is considerable expenditure of human and financial resources associated with regular cleaning of such optical elements, such as transparent windows and solar panels.

The deposition of dirt on such optical elements can be classified into two types: physically bound and chemically bound particulate matter. The physically bound particles are loosely held due to weak physical interactions such as physical entanglement, crevice entrapment, and entrapment of particulates within the nanoscale or microscale edges, steps, terraces, balconies, and boundaries on the uneven surface of the optical element, such as a window surface. These particles can be dislodged with moderate energy forces such as wind, air from a mechanical blower, or by means of water flow induced by rain or other artificially generated sources of flowing water such as a water hose or sprayer. On the other hand, chemically bound particles are characterized by the presence of chemical interactions between the particles themselves and between the particulate matter and the optical element itself, such as glass or acrylics (e.g., plexiglass) used, for example, in windows. In these cases, removal of these particles becomes difficult and usually requires the use of physical means such as high pressure water hoses or manual scrubbing or both. Alternatively, chemical means such as the application of harsh solvents, surfactants, or detergents to the optical element to free the dirt particles from the surfaces can be used. These dirt removal techniques can cause irreparable damage to the antireflective coatings and render the investment in anti-reflective coatings worthless.

As noted, the dirt on ambiently exposed optical elements, such as windows and solar panels, may be somewhat removed based upon natural cleaning phenomenon such as rain. However, rain water is only effective at removing loosely (physically) held particulate matter and is not able to remove the particulate matter that may be strongly (chemically) bonded to optical element, such as the glass or window surfaces. Furthermore, rain water usually contains dissolved matter that is absorbed from the environment during its descent that can leave a visible film when dried.

As such, all externally exposed optical elements, such as window materials and solar panels in which the optimal transmission of light is important, require some form of routine cleaning efforts associated with their maintenance regimen. In fact, the surfaces of these items are cleaned during fabrication as well as routinely during use. The surfaces of these items, such as solar panels, are usually cleaned with water, detergent, or other industrial cleaners. As a result, anti-reflective coating materials applied to these optical elements need to be able to withstand the use of normal cleaning agents including detergents, acid, bases, solvents, surfactants, and other abrasives to maintain their anti-reflective effect. Abrasion of these coatings over time due to cleaning and the deposition of dirt or other environmental particulate may reduce their performance. Therefore, abrasion resistance is an important consideration for anti-reflective coatings. For example, resistance to abrasion is an important consideration for a coating used in connection with a solar panel, particularly for long term functional performance of the solar panel.

A majority of anti-reflective coatings are based on oxides as preferred materials. Some anti-reflective coatings are made of either a very porous oxide-based coating or, alternatively, are comprised of stacks of different oxides. These oxide materials are chemically reactive with dirt particles by means of hydrogen bonding, electrostatic, and/or covalent interactions depending upon the type of coating material and the dirt particle. Therefore, these oxide based coatings have a natural affinity to bind molecules on their surfaces. Further, highly porous coatings can physically trap dirt nanoparticles in their porous structure. As a result, current anti-reflective coatings are characterized by an intrinsic affinity for physical and/or chemical interactions with dirt nanoparticles and other chemicals in the environment and suffer from severe disadvantages in maintaining a clean surface during their functional lifetime.

Further, one of the most common issues associated with anti-reflective coatings is their performance over the entire solar spectrum, particularly with respect to solar panels. While there are several anti-reflective coatings that are only effective in a narrow region of the solar spectrum, for maximum efficiency it is desirable that anti-reflective coatings perform equally well over the entire solar region from 300 nm to 1100 nm. It is also desirable to have the thickness of the anti-reflective coatings to be tuned to match the spectral responsivity of the underlying solar cell. Consequently, there exists a need in the art for a coating that can provide the combined benefits of anti-reflective properties, such as a coating that can reduce light reflection and scattering from the applicable optical surface; anti-soiling or self-cleaning properties, such as a coating surface that is resistant to binding and adsorption of dirt particles (e.g., resistant to chemical and physical bonding of dirt particles); abrasion resistant properties, such as stability against normal cleaning agents such as detergents, solvents, surfactants, and other chemical and physical abrasives; and UV stability or suitable performance over the entire solar region.

Further, it would be beneficial for such coatings to be mechanically robust by exhibiting strength, abrasion resistance, and hardness sufficient to withstand the impact of physical objects in the environment such as sand, pebbles, leaves, branches, and other naturally occurring objects. It would be beneficial for such coatings to also exhibit mechanical stability such that newly manufactured coatings or films would be less likely to develop cracks and scratches that limit their optimum performance, thereby allowing such coatings to be more effective for a relatively longer term of usage. In fact solar panel manufacturers might have a need to specify the abrasion resistance of anti-reflective coatings depending upon a particular geographical region. It is well accepted in the solar industry that soiling of solar panels is a local phenomenon that depends upon the environment where the solar panels are placed. Since the soiling mechanisms are different, the cleaning processes required to clean the solar panels are also different. The cleaning processes employed for cleaning the solar panels are also dependent upon regional and local constraints. In some areas where there is less water available for cleaning dirty solar panels, tightly adhered dust is removed by means of dry brushing which could destroy the antireflective coating and hence render the investment in the antireflective coating worthless after a few cleaning cycles. Areas subject to severe sandstorms could also have antireflective coatings on solar panels destroyed by the abrasive action of sand on the solar panels. Therefore solar panel manufacturers needing to protect their investment in antireflective coatings will need to have antireflective coatings that are highly abrasion resistant.

In addition, it would be beneficial for such coatings to be able to withstand other environmental factors or conditions such as heat and humidity and to be chemically non-interactive or inert with respect to gases and other molecules present in the environment, and non-reactive to light, water, acid, bases, and salts. In other words, it is desirable to provide coatings having a chemical structure that reduces the interaction of the coating with exogenous particles (e.g., dirt) to improve the long term performance of the coating.

The soiling mechanisms of solar panels coated with antireflective coatings and placed in highly urban environments are vastly different from the soiling mechanisms present in dry desert or humid desert environments. Solar panels that are placed in areas that are prone to soiling due to contamination from agricultural activities taking place in a location that is proximal to the solar panels coated with anti-reflective coatings said solar panels might have another mechanism for soiling. It is difficult to have one coating work equally well under all soiling conditions. Therefore it would be beneficial to have anti-reflective coatings with self-cleaning and anti-soiling properties that are tuned to work under different soiling conditions.

Furthermore, some solar panel manufacturers might wish to trade-off higher abrasion resistance for a lower gain in transmission from the anti-reflective coating while some other solar panel manufacturers might wish to optimize the antireflective coating on solar panels by providing a balance between transmission gain, resistance to soiling and resistance to abrasion.

It would also be preferable to enable deposition of such coatings onto the optical surface, such as the surface of a window or solar panel surface, using common techniques such as spin-coating; dip-coating; flow-coating; spray-coating; aerosol deposition; ultrasound, heat, or electrical deposition means; micro-deposition techniques such as ink-jet, spay-jet, or xerography; or commercial printing techniques such as silk printing, dot matrix printing, etc.

It would also be preferable to enable drying and curing of such coatings at relatively low temperatures, such as below 150 C so that the coatings could be applied and dried and cured on substrates to which other temperature sensitive materials had been previously attached, for example a fully assembled solar panel.

Furthermore, while float glass is a familiar material for architectural and photovoltaic applications, it should be recognized that there are some interesting properties of float glass which have not yet been exploited for improving the performance of antireflective coatings on float glass. The process of fabrication of float glass by casting molten soda lime glass on a molten tin bath produces float glass which leads to tin diffusion on the face of the glass in contact with molten tin. The other face, which is in contact with inert atmosphere, is weakly contaminated with tin. Thus float glass is known to be comprised of two composite surface layers and a bulk, one of composite surface being significantly richer in tin concentration compared to the other. It would be beneficial to identify and preferentially coat the tin rich side of float glass with an antireflective coating such that the combined antireflective gain is greater than the antireflective gain obtained by coating the low tin side (air side) of said float glass with said antireflective coating. More specifically, thin film solar panel manufacturers deposit a transparent conducting oxide on the low tin side of float glass. Therefore, it is highly beneficial to have an anti-reflective coating that works cooperatively with the tin rich side of float glass to provide all of the anti-reflective coating's advantageous properties.

For anti-reflective coatings on solar panels, it would also be important to tune and optimize the thickness of the antireflective coating on glass depending upon the type of solar cell that is used by a solar panel manufacturer. This is because the spectral responses for crystalline silicon, amorphous silicon, Cd—Te, CIGS, cells have slight differences and it would be beneficial for the thickness of an antireflective coating to be optimized such that the maximum transmission for the antireflective coating occurs at wavelengths that are well matched to that of the underlying solar cell material.

### SUMMARY

The present disclosure provides coating compositions comprising a silane precursor or combination of silane precursors, a solvent, optionally an acid or base catalyst, and optionally another additive wherein the coating compositions are hydrolyzed to provide a sol that can be optionally coated on the tin rich side of a float glass substrate from which a gel is formed that is subsequently dried and cured to form a coating having a combination of anti-reflective properties, anti-soiling or self-cleaning properties, and abrasion resistance. Accordingly, the anti-reflective coatings provided by the present disclosure are physically, mechanically, structurally, and chemically stable and have a higher transmission compared to coating on the air side of float glass.

In some embodiments, the aforementioned coating compositions can be applied to any substrate wherein a higher transmission of light is required compared to an uncoated surface.

In some embodiments, the coating compositions include a combination of sols containing tetraalkoxysilane, organosilane, and optionally an organofluorosilane that can be coated on the tin rich of float glass for solar panels. In some embodiments, the composition of the coating composition is based upon a precise selection of solvent, pH, solvent to water ratio, and solvent to silane ratio that allows the resulting sol to remain stable for a significant period of time without exhibiting change in its chemical or physical characteristics. In some embodiments, the composition of the coating composition is based upon controlling the precise amounts and/or ratios of the different silanes in the coating composition. The amount of the silanes in the coating composition can be used to control the final thickness of the antireflective coating while the ratio of the different silanes in the coating composition can be used to tune the abrasion resistance and/or transmission and/or anti-soiling and/or self-cleaning property of the anti-reflective coating. The amount of solvent and water in the coating composition can be varied based upon the temperature and humidity of the environment under which the coating will be applied.

The disclosure also provides methods for applying the coatings of the present disclosure and for using such coatings. In some embodiments, the methods of treating a substrate comprises pre-treatment of the substrate based on combination of chemical treatment, etching, and/or polishing or cleaning steps that enable better interaction of the sol with the tin rich surface of float glass for making a thin film or coating with thickness ranging from 50 nm to 200 nm. Thereafter, in some embodiments, the methods include applying the sol to the tin rich surface of the float glass substrate and allowing the sol to gel to form the coating with the desired properties. Pretreatment methods for tempered rolled glass or other kinds of glass substrates could be of a similar nature. It should be apparent to one skilled in the art that different surface preparation conditions will impact the flow of a coating material on the glass and could lead to films with different thickness and abrasion resistance. In some embodiments, the application of the sol to the substrate includes roll coating, drop rolling and/or flow coating that results in uniform deposition of the sol to form an even, uniform and crack-free coating. In some embodiments, the method includes thermally treating the coated articles under specific condition of heat and humidity to form a chemically durable coating that adheres strongly to the substrate without cracking and/or peeling.

In some embodiments, the disclosure provides for the use of the coating compositions as an efficiency enhancement aid in architectural windows in building and houses by the provision of anti-reflection benefits and/or by the provision of anti-soiling benefits to augment the anti-reflection benefits. In other embodiments, the disclosure provides for the use of the coating compositions as an efficiency enhancement aid in treatment of transparent surfaces (that require regular cleaning) to make them self-cleaning.

In some embodiments, the disclosure provides a coated glass-based article suitable for use as outer cover of a solar module assembly that is anti-reflective, hydrophobic and/or oleophobic and exhibits resistance to abrasion, UV light, heat, humidity, corrosives such as acids, bases, salts, and cleaning agents such as detergents, surfactants, solvents and other abrasives.

### BRIEF DESCRIPTION OF THE FIGURES

FIG. 1 illustrates the UV-vis transmittance spectra comparing the transmission gains of coating made from composition given in Example 2.1 on Tin vs Non-Tin side of float glass on a 30 cm×30 cm substrate;

FIG. 2 illustrates the UV-vis transmittance spectra showing maximum transmittance enhancement of coatings on tin side of TCO glass substrates made from compositions given in Example 2.1, 3 and 4;

FIG. 3a is TEM cross-sectional view of a coating made from the composition of Example 2 on a glass slide substrate;

FIG. 3b is a High resolution TEM of a coating made from the composition of Example 2 on a glass substrate;

FIG. 4 is an SEM cross-sectional view of a coating made from the composition of Example 2.1 on a 30 cm×30 cm glass substrate;

FIG. 5 is an SEM cross-sectional view of a coating made from the composition of Example 3 on a 30 cm×30 cm glass substrate;

FIG. 6 is an SEM cross-sectional view of a coating made from the composition of Example 4 on a 30 cm×30 cm glass substrate;

FIG. 7a is a GPC of sol made from Example 2;

FIG. 7b is an expanded view of the GPC of sol made from Example 1 showing the spread of the molecular weights for sol made from Example 2;

FIG. 8a is the XPS spectrum of coating from Example 2.1 on tin side of TCO coated glass; and

FIG. 8b is the XPS spectrum of coating from Example 2.1 on tin side of TCO coated glass after 10 minute Argon Sputter Etch.

### DETAILED DESCRIPTION

Various embodiments of the disclosure are described below in conjunction with the Figures; however, this description should not be viewed as limiting the scope of the present disclosure. Rather, it should be considered as exemplary of various embodiments that fall within the scope of the present disclosure as defined by the claims. Further, it should also be appreciated that references to “the disclosure” or “the present disclosure” should not be construed as meaning that the description is directed to only one embodiment or that every embodiment must contain a given feature described in connection with a particular embodiment or described in connection with the use of such phrases. In fact, various embodiments with common and differing features are described herein.

The present disclosure is generally directed to coatings that provide a noticeable improvement in anti-reflective properties when coated on the tin rich side of float glass. It is the combination of the improved anti-reflective properties with the anti-soiling properties, self-cleaning properties and manufacturing flexibility as well as other benefits that further enhances the utility of the coating. Accordingly, the coatings of the present disclosure may be used on substrates, such as transparent substrates, to increase the light transmittance through the substrates. In particular, the coatings may be used on transparent substrates such as glass or the front cover glass of solar panels.

The present disclosure is particularly well suited for use with glass used in solar energy generation (“solar glass”). It should be understood that solar energy generation includes solar photovoltaic and solar thermal, wherein solar insolation is used to produce heat either as an end-point or as an intermediate step to generate electricity. Furthermore it should be understood that solar glass may be used in any application where maximal transmission of solar energy through the glass is desired such as for example in greenhouses. Typically solar glass is high transmission low iron glass. It may be either float glass, that is, flat glass sheets formed on a molten tin bath or rolled glass wherein the flat glass is formed by the action of rollers. Float glass is often characterized by the presence of tin contamination on the bottom (“tin side”) of the glass. Rolled glass is typically textured on one side to improve its performance in solar panels. It may also be formed into tubes such as those used as receivers in solar thermal energy generation or in some forms of solar photovoltaic generation. The present disclosure may also be applied to glass surfaces used as mirrors in solar energy generation such as parabolic trough systems or in heliostats. It may also be used to coat various glass lenses such as Fresnel lenses used in solar thermal generation.

Additionally, solar glass may have various coatings applied. For example a common coating is a transparent conductive oxide (TCO) such as Indium Tin Oxide (ITO) on one side of the glass. This coating is used to provide the front electrode for many thin film solar panel technologies. Other coatings may be present such as coatings to seal in alkali ions such as Na+ and Ca+ that are used in the manufacturer of the glass but that cause long term reliability problems when leached out by water. Other techniques to solve this problem are to deplete these ions in thin layers of the glass surface. Solar glass may also be coated with a reflective surface to form a mirror. Solar glass may be tempered or untempered. Tempered glass is significantly stronger and solar panels manufactured using it typically only need one sheet of glass. Solar panels manufactured with untempered front glass typically need a back sheet of tempered glass to meet strength and safety requirements. Many thin-film solar photovoltaic technologies also use the front glass as a substrate upon which they deposit materials that comprise the solar cell. The processes used during the manufacturer of the solar cell may adversely affect the properties of any existing coatings on the glass or existing coatings may interfere with the solar cell manufacturing process. The present disclosure is completely tolerant of type of glass selected by the solar panel manufacturer. It works equally well on float or rolled glass.

One critical issue for solar panel manufacturers that use TCO (or similar) coated glass is tempering. It is very difficult to achieve low-cost, high quality TCO coated tempered glass. Therefore solar panel manufacturers that requite TCO coated glass use untempered glass, necessitating the use of a second sheet of tempered glass on the back side of the solar panel. Additionally even if suitable TCO coated tempered glass was available some thin-film solar manufacturing processes heat the glass during manufacturer to the extent that the temper is lost. All existing anti-reflective glass on the market is tempered, because the anti-reflective coatings using the sol-gel process is actually formed during the tempering process. Tempering is the process by which the glass is heated to 600° C. to 700° C., then quickly cooled. This high tempering temperature effectively sinters the anti-reflective coating providing it with its final mechanical strength. Thus solar panel manufacturers that cannot use tempered glass typically cannot use anti-reflective glass. In addition, some module manufacturers, especially thin film module manufacturers who might need to apply anti-reflective coatings on finished or substantially finished modules are unable to use currently available sol-gel coatings because they need to be cured at temperatures greater than 300° C. or exposed to a corrosive ammonia atmosphere or exposed to highly toxic acids like hydrofluoric acid. Exposing finished or substantially finished solar modules to temperatures >300° C. or exposing them to a corrosive ammonia atmosphere is likely to damage their performance and/or long term reliability. Exposing finished modules to acids or other strong etchants to create a graded refractive index layer is equally challenging and poses an additional safety risk due to managing and disposing large quantities of a highly dangerous chemical like hydrofluoric acid. The present disclosure may be applied and cured at a low temperature of between 20° C. and 200° C. and between 20° C. and 130° C. and further between 80° C. and 200° C. This low temperature facilitates the coating of completed solar panels without damage to the panel. Thus it is an anti-reflective solution for users of untempered solar glass and for users of anti-reflective coatings on finished or substantially finished solar modules.

The low temperature curing of the present disclosure also provides substantial benefits to solar panel manufacturers beyond enabling untempered anti-reflective glass. By making possible the coating of the glass without the need for the tempering step, solar panel manufacturers are enabled to apply their own anti-reflective coating. Currently the requirement for a large tempering oven means that solar panels manufacturers are restricted to buying anti-reflective glass from glass manufacturers. This means that they must maintain inventory of both anti-reflective coated and non-coated glass. As these cannot be used interchangeably inventory flexibility is reduced necessitating keeping larger amounts of inventory on hand. The ability for the solar panel manufacturer to apply their own coating means that they can just hold a smaller inventory of non-coated glass and then apply the anti-reflective coating to that as needed.

In addition, existing anti-reflective coatings are prone to scratching during the solar panel manufacturing process. Typically solar panel manufacturers must use a plastic or paper sheer to protect the coating. As the coating of the present disclosure can be applied to fully manufactured solar panels, it can be applied at the end of the manufacturing process thus removing the need for the protection sheet and the opportunity for damage to the coating during manufacture.

Existing anti-reflective coatings from different manufacturers tend to have subtle color, texture and optical differences. This presents problems to solar panel manufacturers who desire their products to have a completely consistent cosmetic finish. If they manufacturer large numbers of solar panels it is almost inevitable that they will have to order anti-reflective glass from different suppliers causing slight differences in the appearance of the final products. However, the coating of the present disclosure enables solar panel manufacturers to apply their own coating and so enables cosmetic consistency over an unlimited number of solar panels.

In addition, to their anti-reflective properties, the coatings described herein exhibit anti-soiling and/or self-cleaning properties, as they are resistant to the adhesion of dirt and promote the removal of any adhered dirt by the action of water. More specifically, the coatings described herein are characterized by extremely fine porosity that minimizes the deposition of dirt by physical means. Further, these coatings are characterized by a low energy surface that resists chemical and physical interactions and makes it easy to dislodge the particles, thereby making the surfaces essentially anti-soiling. The reduced physical and/or chemical interactions with the environment, such as dirt, make the exposed surface of these coating less susceptible to binding of dirt and also make it easier to clean with a minimal expenditure of force or energy.

Typically in order to completely clean ordinary glass a mechanical action for example brushes or high pressure jet is required to dislodge dirt that is strongly adhered to the surface. However the coating of the present disclosure presents a surface such that dirt is much more attracted to water then to the surface. Thus in the presence of water any dirt resting on the surface is efficiently removed without the need for mechanical action. This means that coated glass will achieve a high level of cleanliness in the presence of natural or artificial rain without human or mechanical intervention. In addition, the amount of water required to clean the glass is substantially reduced. This is of special significance given that the most effective locations for solar energy generation tend to be sunny warm and arid. Thus water is a particularly expensive and scarce resource in the very locations that solar energy is most effective.

The present disclosure enables a significant reduction in the Levelized Cost of Energy (LCOE) to the operator of a solar energy generating system. First, the anti-reflective property increases the efficiency of the solar panels. Increased efficiency enables a reduction of cost in the Balance Of System (BOS) costs in construction of the solar energy generation system. Thus for a given size of system the capital costs and construction labor costs are lower. Second, the anti-soiling property increases the energy output of the solar panels by reducing the losses due to soiling. Third the Operating and Maintenance (O&M) costs are reduced because fewer or no washings are needed eliminating labor and water cost associated with washing.

The coatings described herein also contain water and oil resistant hydro/fluoro-carbon groups that make them chemically non-reactive and non-interacting. When used in combination with a glass substrate, the coatings bind to the glass surface using siloxane linkages that make them adhere strongly and makes them strong, durable, and abrasion and scratch resistant. In summary, these coatings are physically and chemically nonreactive, mechanically and structurally stable, hydrophobic, oleophobic, and stable across the UV spectrum. Accordingly, it should be appreciated that the coatings described herein have particular application to transparent substrates that are exposed to the environment, such as exterior windows and the front cover glass of solar panels.

Generally, the coatings described herein are prepared by a sol-gel process. The starting composition, referred to as a “coating mixture” or “coating composition,” includes a silane precursor or a combination of silane precursors that when hydrolyzed and condensed forms a particulate suspension of particles in a liquid sol. This sol can be coated onto a substrate using coating techniques known in the art, gelled to form a gel, and dried to form a hard layer or coating having the properties noted above. The process of curing the dried gel further hardens it.

Generally, the resulting properties of the coating described above are provided by using a particular combination of components in the formation of the final coating. In particular, the selection of a particular silane precursor or mixture of silane precursors in combination with other components in the coating mixture is important in providing a coating with the desired properties. For example, in some embodiments, the coatings are made from a mixture of silane precursors including alkoxysilane, organosilane, and optionally, organofluorosilane. In some embodiments, separate coating mixtures or mixtures of silane precursors can be used to form separate sols that may then be combined to form a final sol that is applied to a substrate to be coated. Further, a single sol, or separately prepared sols that are combined together, may be combined with another silane precursor to form a final sol that is applied to a substrate to be coated.

For example, tetraalkoxysilanes when hydrolyzed form an extensively cross-linked structure due to the formation of four Si—O—Si linkages around each silicon atom. These structures are characterized by mechanical stability and abrasion resistance. To impart hydrophobicity to the ultimate coating, organically-modified silanes (such as methyltrimethoxysilane) can be used in addition to the tetraalkoxysilane. Further, to impart oleophobicity and anti-soiling characteristics, organofluorosilanes can be used in addition to the tetralkoxysilane.

It should be appreciated that the coating material and process by which it is applied to the substrate comprise a larger coating system. The coating material is optimized for a particular coating method and vice versa. Thus the optimized coating process is preferentially performed by a custom designed tool to insure consistency and quality. Therefore this tool coupled with the coating materials comprises the coating system. Given that the benefits of the current disclosure are particularly well suited to solar panel manufacturers, who do not themselves manufacture tools, it is desirable to offer a complete solution consisting of both the coating material and its associated coating tool. In the following paragraphs describing the coating process it should be appreciated that these steps could be executed manually, automatically using a coating tool or in any combination of both.

Furthermore, the custom designed coating tool may be a large stand-alone unit intended for operation in a factory setting; it could be a sub-tool, such that it comprises a process module that performs the coating process but that is integrated into another machine that performs other steps in the larger solar panel manufacturing process. For example it could be a module attached to an existing glass washing machine or a module attached to a panel assembly machine. Alternatively, the tool could be portable or semi-portable, for example mounted on a truck or inside a tractor trailer such that it could be transported to a worksite and used to coat solar modules during the construction of a large solar installation. Alternatively it could be designed such that the coating could be applied to installed solar modules in situ.

In general, three steps are used to apply the sol to a given substrate. First, the substrate is cleaned and prepared. Second, the substrate is coated with the sol or mixture of sols. Third, the final coating is formed on the substrate.

As an initial step, the substrate is pre-treated or pre-cleaned to remove surface impurities and to activate the surface by generating a fresh surface or new binding sites on the surface. The substrate pre-treatment steps are important in providing uniform spreading and deposition of the sol, effective bonding interactions between the substrate and coating material for Si—O—Si linkage formation, and prevention of defects and imperfections at the coating-substrate interface because of uneven spreading and/or diminished bonding interactions due to surface inhomogeneities.

In particular, it is desirable to expose Si—OH groups on the surface of the substrate through pre-treatment or cleaning of the substrate surface to form an “activated” surface. An activated surface layer lowers the surface tension of the predominantly hydrophilic solvents in the sol and enables effective spreading of the sol on the surface. In some embodiments, a combination of physical polishing or cleaning and/or chemical etching is sufficient to provide even spreading of the sol. In cases, where the surface tension would need to be further lowered, the substrate, such as glass, may be pretreated with a dilute surfactant solution (low molecular weight surfactants such as surfynol; long chain alcohols such as hexanol or octanol; low molecular weight ethylene oxide or propylene oxide; or a commercial dishwasher detergent such as CASCADE, FINISH, or ELECTRASOL to further help the sol spread better on the glass surface.

Accordingly, surface preparation involves a combination of chemical and physical treatment of the surface. The chemical treatment steps include (1) cleaning the surface with a solvent or combination of solvents, detergents, mild bases like sodium carbonate or ammonium carbonate (2) cleaning the surface with a solvent along with an abrasive pad, (3) optionally chemically etching the surface, and (4) washing the surface with water. The physical treatment steps include (1) cleaning the surface with a solvent or combination of solvents, (2) cleaning the surface with a solvent along with particulate abrasives, and (3) washing the surface with water. It should be appreciated that a substrate can be pre-treated by using only the chemical treatment steps or only the physical treatment steps. Alternatively, both chemical and physical treatment steps could be used in any combination. It should be further appreciated that the physical cleaning action of friction between a cleaning brush or pad and the surface is an important aspect of the surface preparation.

In the first chemical treatment step, the surface is treated with a solvent or combination of solvents with variable hydrophobicity. Typical solvents used are water, ethanol, isopropanol, acetone, and methyl ethyl ketone. A commercial glass cleaner (e.g., WINDEX) can also be employed for this purposes. The surface may be treated with an individual solvent separately or by using a mixture of solvents. In the second step, an abrasive pad (e.g., SCOTCHBRITE) is rubbed over the surface with the use of a solvent, noting that this may be performed in conjunction with the first step or separately after the first step. In the last step, the surface is washed or rinsed with water.

One example of substrate preparation by this method involves cleaning the surface with an organic solvent such as ethanol, isopropanol, or acetone to remove organic surface impurities, dirt, dust, and/or grease (with or without an abrasive pad) followed by cleaning the surface with water. Another example involves cleaning the surface with methyl ethyl ketone (with or without an abrasive pad) followed by washing the surface with water. Another example is based on using a 1:1 mixture of ethanol and acetone to remove organic impurities followed by washing the surface with water.

In some instances an additional, optional step of chemically etching the surface by means of concentrated nitric acid, sulfuric acid, or piranha solution (1:1 mixture of 96% sulfuric acid and 30% H₂O₂) may be necessary to make the surface suitable for bonding to the deposited sol. Typically this step would be performed prior the last step of rinsing the surface with water. In one embodiment, the substrate may be placed in piranha solution for 20 minutes followed by soaking in deionized water for 5 minutes. The substrate may then be transferred to another container holding fresh deionized water and soaked for another 5 minutes. Finally, the substrate is rinsed with deionized water and air-dried.

The substrate may alternatively or additionally prepared by physical treatment. In the physical treatment case, for one embodiment the surface is simply cleaned with a solvent and the mechanical action of a cleaning brush or pad, optionally a surfactant or detergent can be added to the solvent, after which the substrate is rinsed with water and air dried. In another embodiment the surface is first cleaned with water followed by addition of powdered abrasive particles such as ceria, titania, zirconia, alumina, aluminum silicate, silica, magnesium hydroxide, aluminum hydroxide particles, or combinations thereof onto the surface of the substrate to form a thick slurry or paste on the surface. The abrasive media can be in the form a powder or it can be in the form of slurry, dispersion, suspension, emulsion, or paste. The particle size of the abrasives can vary from 0.1 to 10 microns and in some embodiments from 1 to 5 microns. The substrate may be polished with the abrasive slurry via rubbing with a pad (e.g., a SCOTCHBRITE pad), a cloth, or paper pad. Alternatively, the substrate may be polished by placement on the rotating disc of a polisher followed by application of abrasive slurry on the surface and rubbing with a pad as the substrate rotates on the disc. Another alternative method involves use of an electronic polisher that can be used as a rubbing pad in combination with abrasive slurry to polish the surface. The substrates polished with the slurry are cleaned by pressurized water jet and air-dried.

After pretreating the surface, the final sol is deposited on a substrate by techniques known in the art, including roll-coating, dip coating, spraying, drop rolling, or flow coating to form a uniform coating on the substrate. Other methods for deposition that can be used include spin-coating; aerosol deposition; ultrasound, heat, or electrical deposition means; micro-deposition techniques such as ink-jet, spay-jet, xerography; or commercial printing techniques such as silk printing, dot matrix printing, etc. Deposition of the sol is typically done under ambient conditions.

In some embodiments, the method of deposition is performed via the drop rolling method on small surfaces wherein the sol composition is placed onto the surface of a substrate followed by tilting the substrate to enable the liquid to roll across the entire surface. For larger surfaces, the sol may be deposited by flow coating wherein the sol is dispensed from a single nozzle onto a moving substrate at a rate such that the flowing sol leads to a uniform deposition onto a surface or from multiple nozzles onto a stationary surface or from a slot onto a stationary surface. Another method of deposition is via depositing the liquid sol onto a substrate followed by use of a mechanical dispersant to spread the liquid evenly onto a substrate. For example, a squeegee or other mechanical device having a sharp, well-defined, uniform edge may be used to spread the sol.

The thickness of the coatings deposited can vary from about 10 nm to about 5 micron. In some embodiments, the thickness of the coating varies from about 100 nm to about 1 micron, and in other embodiments it varies from about 100 nm to about 500 nm. In order to provide sufficient anti-reflective properties, a thickness of about 60 nm to about 150 nm is desired. It should be appreciated that the thickness of the coating mixture as deposited is affected by the coating method, as well as the viscosity of the coating mixture. Accordingly, the coating method should be selected so that the desired coating thickness is achieved for any given coating mixture.

Once the final sol is deposited as described above, the deposited sol will proceed to form a gel through the process of gelation after which the gel is dried and cured to remove residual solvent and facilitate network formation via Si—O—Si linkage formation in the coating. In addition, the gel may be allowed to age to allow for the formation of additional linkages through continued hydrolysis and condensation reactions.

As described above, the sol-gel method used in preparing the coatings described herein utilizes a suitable molecular precursor that is hydrolyzed to generate a solid-state polymeric oxide network. Initial hydrolysis of the precursor generates a liquid sol, which ultimately turns to a solid gel. Drying of the gels under ambient conditions (or at elevated temperature) leads to evaporation of the solvent phase to form a cross-linked film. Accordingly, throughout the process, the coating mixture/sol/gel/dried/cured coating undergoes changes in physical, chemical, and structural parameters that intrinsically alter the material properties of the final coating. In general, the changes throughout the sol-gel transformation can be loosely divided into three interdependent aspects of physical, chemical, and structural changes that result in altered structural composition, morphology, and microstructure. The chemical composition, physical state, and overall molecular structure of the sol and the gel are significantly different such that the materials in the two states are intrinsically distinct.

Regarding physical differences, the sol is a collection of dispersed particles suspended in a liquid. These particles are surrounded by a solvent shell and do not interact with each other significantly. As such, the sol is characterized by fluidity and exists in a liquid state. In contrast, in a gel film the network formation has occurred to an advanced state such the particles are interconnected to each other. The increased network formation and cross-linking makes the gel network rigid with a characteristic solid state. The ability of the material to exist in two different states is because of the chemical changes that occur along the sol to gel transformation.

Regarding chemical changes, during the sol to gel transition, the sol particles combine with each other via formation of Si—O—Si linkages. As a result, the material exhibits network formation and strengthening. Overall, the sol particles contain reactive hydroxyl groups on the surfaces that can participate in network formation while the gel structure has these hydroxyl groups converted into siloxane groups.

Regarding structural differences, the sol contains discrete particles containing few siloxane linkages along with terminal hydroxyl as well as unhydrolyzed alkoxy ligands. As such, the sol state can be considered structurally different from the solidified films which contain majority siloxanes. As such, the liquid sol and the solid state polymeric networks are chemically and structurally distinct systems.

Regarding differences in properties, the origin of the physical and chemical properties of the sol and gel films depends upon their structure. The sol particles and the gel films differ in the chemical composition, makeup and functional groups and as a result exhibit different physical and chemical properties. The sol stage because of its particulate nature is characterized by high reactivity to form the network while the gel state is largely unreactive due to conversion of reactive hydroxyl groups to stable siloxane linkages. Accordingly, it should be appreciated that it is the particular combination of silane precursors and other chemicals added to the coating mixture that is hydrolyzed and condensed, gelled, dried and cured on a substrate surface that gives the final coatings of the present disclosure the desired properties described above.

There are several methods by which the gel is dried and cured and/or aged to form the final coating. In some embodiments the gel is dried and cured under ambient or room temperature conditions. In some embodiments, the gel is aged under ambient conditions for 30 minutes followed by drying for 3 hours in an oven kept at a variable relative humidity of (e.g., 20% to 50%). The temperature of the oven is then increased slowly at a rate of 5 degrees Celsius/min to a final temperature of 120 degrees Celsius. The slow heating rate along with the moisture slows the rate of the silanol condensation reaction to provide a more uniform and mechanically stable coating. This method provides reproducible results and is a reliable method of making the coating with the desired properties.

In another embodiment, the gel on the substrate is heated under an infrared lamp or array of lamps. These lamps are placed close proximity to the substrate's coated surface such that the surface is evenly illuminated. The lamps are chosen for maximum emission in the mid-infrared region of 3˜5 um wavelength. This region is desirable because it is adsorbed better by glass than shorter infrared wavelengths. The power output of the lamps may be closely controlled via a closed loop PID controller to achieve a precise and controllable temperature profile. In some embodiments this profile will start from ambient temperature and quickly rise 1˜50 degrees centigrade per second to a temperature of 120 degrees Celsius, hold that temperature for a period of 30 to 300 seconds, then reduce temperature back to ambient, with or without the aid of cooling airflow.

For applications requiring high throughput and/or for applications wherein there is a process sensitivity around the maximum allowable temperature for the bottom surface of the coated glass when the glass is cured it would be preferred to cure the glass such that only the top surface of the glass is heated by impinging hot air on the coated surface or a xenon arc lamp using a pulsing method where the lamp is turned on and off multiple times during the cure cycle.

As described above and as illustrated further in the Examples, the coatings made as described herein have several desirable properties. The coatings have anti-reflective properties that reduce the reflection of photons. The transmittance of a glass substrate coated with a coating composition made according to the present disclosure can be increased by about 1-8%, from about 2% to about 6%, and from about 1% to about 4% relative to uncoated glass substrates

The coatings also have anti-soiling properties, which are also important in maintaining sufficient transmittance when used in conjunction with a glass substrate. Soiling is due to adherence of particulate matter on surfaces exposed to environment. The deposition of the particles onto surfaces depends upon the surface microstructure as well as chemical composition. In general, rough surfaces can provide many sites for physical binding of particulate matter. For solar panels, soiling can lead to reduction in power output due to reduced absorption of light of typically about 5% and in some cases losses of 22% have been reported. The paper “The Effect of Soiling on Large Grid-Connected Photovoltaic Systems in California and the Southwest Region of the United States”, Photovoltaic Energy Conversion, Conference Record of the 2006 IEEE 4th World Conference, May 2006, Vol. 2, p 2391-2395, reports an average 5% loss. The paper “Soiling and other optical losses in solar-tracking PV plants in Navarra”, Prog. Photovolt: Res. Appl. 2011; 19:211-217, reports losses of 22%.

The chemical composition of the surfaces is reflected in the surface energy as measured by contact angles. Low energy surfaces (characterized by high water contact angles) are usually less susceptible to binding as compared to high energy surfaces with low water contact angles. Therefore, anti-soiling properties can be determined indirectly by measuring the coating's contact angle. The coatings herein provide contact angles ranging from about 10 degrees to about 178 degrees, from about 110 degrees to about 155 degrees, and from about 125 degrees to about 175 degrees. The coatings of this disclosure minimize the photon flux losses due to soiling by about 50% relative to uncoated samples.

The coatings of the present disclosure also provide tunable mechanical properties. Nano-indentation is a method of used to measure the mechanical properties of nanoscale materials especially thin films and coatings. The testing instrument that is used for performing the nanoindentation tests is a Nanomechanical Test System (manufactured by Hysitron, Inc., USA). This Nanomechanical Test System is a high-resolution nanomechanical test instrument that performs nano-scale quasi-static indentation by applying a force to an indenter tip while measuring tip displacement into the specimen. During indentation, the applied load and tip displacement are continuously controlled and/or measured, creating a load-displacement curve for each indent. From the load-displacement curve, nano-hardness and reduced elastic modulus values can be determined by applying the Oliver and Pharr method and a pre-calibrated indenter tip area function and a pre-determined machine compliance value. The instrument can also provide in-situ SPM (scanning probe microscopy) images of the specimen before and after indentation. Such nanometer resolution imaging function is accomplished quickly and easily by utilizing the same tip for imaging as for indentation. The in-situ SPM imaging capability is not only useful in observing surface features, but also critical in positioning the indenter probe over such features for indentation tests.

Typically nanohardness and reduced elastic modulus will be determined using nanoindentation. The reduced elastic modulus has a relationship with the Young's modulus as shown in Equation 1. If Poisson's ratio for the material to be tested is known then Young's modulus of it can be calculated. The Poisson's ratio for the diamond indenter is 0.07 and the Young's modulus of the indenter is 1141 GPa.

$$\frac{1}{{E}_{r}} = \frac{( 1 - {v}_{material}^{2} )}{{E}_{material}} + \frac{( 1 - {v}_{indenter}^{2} )}{{E}_{indenter}} \qquad Eq . 1$$

The nanoindentation tests were performed on 1 cm² samples cut from coated glass specimens made according to composition of Example 2 and Example 3. To obtain the hardness and modulus values for the coating, ten indents were performed on each sample. Loads of 15 μN were used for Sample 5F and 25 μN for Sample 7J. All indents were performed through in-situ SPM imaging. Table 1 summarizes the test conditions and parameters used in the nanohardness and modulus tests.

TABLE 1
Nanohardness and Modulus Testing Conditions and Parameters

| | |
|---|---|
| Specimens | Sample 5F and Sample 7J |
| Test instrument | TriboIndenter |
| Indentation Load | 15, 25 μN |
| Indenter Probe Tip | Diamond Berkovich indenter tip |
| Temperature | 74° F. |
| Humidity | 25% RH |
| Environment | Ambient air |

Tables 2 and 3 present the nanohardness, H, and reduced elastic modulus, Er, measurement results. These tables also show values for the contact depth, hc, of each indent. The test locations of these indents were chosen to ensure adequate spacing between measurements.

From Tables 2 and 3, it can be known that the average nanohardness was highest for Sample 7J (2.11 GPa) and lowest for Sample 5F (1.43 GPa). Average reduced elastic modulus was highest for Sample 7J (20.99 GPa) lowest for Sample 5F (13.51 GPa). These results further confirm that the hardness of the coatings of the disclosure can be tuned by changing the ratios of organosilane, alkoxysilane and fluorosilanes in the synthesis of sols from which the coatings are obtained.

TABLE 2
Nanohardness and Reduced Elastic Modulus Test Results
for Sample 5F - Film Made from Composition of Example 2

| Test | | | |
|---|---|---|---|
| Under | H | Er | hc |
| 15 μN | (GPa) | (GPa) | (nm) |
| 1 | 1.46 | 13.93 | 15.24 |
| 2 | 1.45 | 13.67 | 15.16 |
| 3 | 1.48 | 13.38 | 14.98 |
| 4 | 1.46 | 13.21 | 15.13 |
| 5 | 1.48 | 13.37 | 15.02 |
| 6 | 1.34 | 13.50 | 16.04 |
| 7 | 1.46 | 13.55 | 15.23 |
| 8 | 1.43 | 13.95 | 15.40 |
| 9 | 1.43 | 13.57 | 15.41 |
| 10 | 1.34 | 13.00 | 16.06 |
| Average | 1.43 | 13.51 | 15.37 |
| St. Dev | 0.05 | 0.30 | 0.39 |

TABLE 3
Nanohardness and Reduced Elastic Modulus Test Results
for Film 7J - Film Made from Composition of Example 3

| Test | | | |
|---|---|---|---|
| Under | H | Er | hc |
| 25 μN | (GPa) | (GPa) | (nm) |
| 1 | 2.09 | 20.76 | 15.87 |
| 2 | 2.04 | 20.75 | 16.10 |
| 3 | 2.09 | 20.53 | 15.72 |
| 4 | 2.27 | 21.75 | 14.99 |
| 5 | 2.08 | 21.15 | 15.82 |
| 6 | 2.13 | 21.40 | 15.59 |
| 7 | 2.09 | 20.78 | 15.80 |
| 8 | 2.03 | 21.20 | 16.09 |
| 9 | 2.15 | 21.22 | 15.59 |
| 10 | 2.11 | 20.30 | 15.78 |
| Average | 2.11 | 20.99 | 15.73 |
| St. Dev | 0.07 | 0.44 | 0.31 |

The coatings of the present disclosure also provide desirable abrasion resistance. Abrasion resistance can be defined as the ability of a material to withstand erosion due to frictional forces to preserve and maintain its original shape and appearance. Abrasion resistance relates to the strength of the intrinsic framework structure as well as to surface features. Materials that do not have sufficient strength due to lack of long range bonding interactions tend to abrade easily. Similarly, materials with uneven surfaces or coatings with surface inhomogeneities and asperities tend to wear due to frictional losses. Also, the leveling and smoothening of these asperities due to friction leads to changes in optical transmission of the coating as the material is abraded.

The coatings of the present disclosure pass the standard test for measuring abrasion resistance of coatings on surfaces as defined according to European Standard EN-1096-2 (Glass in Building, Coated Glass). The test involves the action of rubbing a felt pad on the coated glass. The felt rubbing pad is subjected to a to-and-fro translation motion with a stroke length of 120±5 mm at a speed of 54-66 strokes/min combined with a continuous rotation of the pad of 6 rpm or of a rotation of between 10° to 30° at the end of each stroke. The back and forth motion along with the rotation constitutes 1 cycle. The specifications of the circular felt rubbing pad include a diameter of 14-15 mm, thickness of 10 mm and density of 0.52 g/cm². The felt pad is attached to a mechanical finger that is 15 mm to 20 mm is diameter and placed under a load of 4 Newtons. The transmission between 340 nm and 1000 nm is measured to evaluate abrasion resistance and the standard dictates a change in transmission of no more that ±0.5% with respect to a reference sample.

TABLE 4
Varying of Abrasion Resistance by Changing
the Ratio of Precursors on Tin-Sided TCO Glass

| | Pre-Abrasion Transmission | Post-Abrasion Transmission |
|---|---|---|
| Composition | Gain | Gain |
| Example 2.1 | 2.56 | 1.69 |
| Example 3 | 2.38 | 2.16 |
| Example 4 | 1.79 | 1.69 |

The coatings of the present disclosure have abrasion resistance that can be tuned or modulated in a variety of ways. Table 4 demonstrates how the abrasion resistance of the coatings from this disclosure can be tuned or modulated by changing sol composition from which the coatings are obtained. It would be beneficial to be able to provide coatings as in Example 3 that have a higher durability against abrasion for solar panels or glass substrates that are exposed to abrasive natural environments like sandstorms or cleaning actions that involve contacting the antireflective coatings with abrasives. In areas where the solar panels are unlikely to be exposed to significant it might be more beneficial to provide coatings that have a higher pre-abrasion transmission as in Example 2.1.

It is possible that the beneficial properties of the coating can also be tuned by changing the molecular weight of the sols that comprise the coating or changing the ratio of low and high molecular weight components in the sols that comprise the coating or by the changing the polydispersity of the sols that comprise the coating. For example, changing the polydispersity of the sols could impact how the polymerized silane molecules pack together. This could have an impact on abrasion resistance of the cured coating. Another example is modifying the surface characteristics of the final coating by the presence of low molecular weight hydrolyzed fluorosilane molecules in the sol. As the coating dries, these low molecular weight species could rise to the coatings surface and modify the wettability of the coating and thereby alter its anti-soiling and/or self-cleaning properties.

Gel Permeation Chromatography is a technique that is used to characterize the molecular weight of polymers. We have used both Agilent and Waters GPC systems for analysis and found the results to be in agreement. The method details are as follows HPLC: 1525 pump (used as a 1515 isocratic pump) equipped with a manual Rheodyne injector and 20 uL loop, 2414 RI detector with column heater. Column and detector oven heated to 4° C. Flow used was 0.3 ml/min. Two 4.6×300 mm GPC columns inline: Styragel HR 1 plus Styragel HR 2 for an effective MW range were used. The columns came pre-equilibrated in THF and THF was used as the eluent. Polystyrene narrow standards were used and the standard curve was fit to a 3rd-order polynomial. Six polystyrene standards from approx 530 MW to 20,000 were used. The PS standards were prepared at 10 mg/ml each in THF and diluted their samples 1:10 in THF for injections. Results are shown in FIG. 7a and FIG. 7b for sol made from Example 2. It can be seen that the sols used for preparation of coatings in this disclosure have a molecular weight that is less than 1000.

Yet another way to modulate the abrasion resistance of the coatings of the present disclosure is by changing the temperature at which the coatings are cured after drying. Similar films when cured at ambient temperature typically will have a lower abrasion resistance compared to films cured at 120 C which can be lower than films cured at 200 C or 300 C in a conventional oven.

In general, the various coatings of the present disclosure provide a means of making a transparent substrate or glass transmit more photons without altering its intrinsic structure and other properties, along with passivating the surface so that it becomes resistant to the adhesion of water, dirt, soil, and other exogenous matter. Accordingly, the coating mixtures and resulting gels and coatings as described herein have varied commercial applications.

Regarding the coating mixtures themselves, these may be sold as a coating mixture or commercial coating formulation for others to use. For example, the coating mixtures may be provided as a liquid composition, for example, for subsequent small scale treatment of glass in a treatment separate from their usage as windows in solar or architectural systems. In this case the coating mixture may be sold before the silane precursors are hydrolyzed. Alternatively, the coating mixtures may be sold as sols or after the silane precursors have been hydrolyzed.

In addition, the coating mixtures may be deposited and allowed to gel on a particular substrate that is subsequently sold. In particular, the coating compositions of the present disclosure can be coated onto any transparent substrate that has hydrogen bond donor or hydrogen bond acceptor groups on the surface. For example, the coating can be applied as a treatment for a given glass or other transparent substrate before or after it has been integrated into a device, such a solar cell, optical window or enclosure, for example, as part of a glass treatment process. In other embodiments, the disclosure provides for the use of the coating compositions as an efficiency enhancement aid in architectural windows in building and houses by the provision of anti-reflection benefits and/or by the provision of anti-soiling benefits to augment the anti-reflection benefits. In other embodiments, the disclosure provides for the use of the coating compositions as an efficiency enhancement aid in treatment of transparent surfaces that require regular cleaning to make them self-cleaning. For example, the coatings can be used in conjunction with glass used in windows, windshields, screens, architecture, goggles, eyeglasses, etc.

In other embodiments, the disclosure provides for the use of the coating compositions as an efficiency enhancement aid in photovoltaic solar panel assemblies (e.g., the outer cover of solar panels) by the provision of anti-reflection benefits and/or by the provision of anti-soiling benefits to augment the anti-reflection benefits. These devices convert solar energy into electrical energy and rely upon efficient absorption of photons, and effects such as reflection, scattering, and loss of absorption due to adsorbed soil or dirt particles can lead to reduced power output. As noted, the coatings of this disclosure when coated onto a glass surface reduces reflection of photons (the so-called anti-reflective property) and also reduces adsorption and binding of dirt, soil, and other particulate matter from the environment to boost the transmission of photons through the glass as well as to prevent reduction in photons associated with deposition of particulate matter onto the surface.

The coatings for solar panel applications provide unique challenges that are not present with coatings typically utilized in other common applications. The use of anti-reflective coating in solar panels necessitates long term exposure of solar radiation that usually results in extensive degradation of polymeric materials under prolonged UV exposure due to photolytic breakdown of bonds in these materials. The coating compositions of the present disclosure utilize silane precursors that when hydrolyzed and dried and cured give rise to a network that is similar to glass with Si—O—Si bonds that are stable to radiative breakdown. An additional advantage of using silica based materials in solar applications is the intrinsic hardness of the material that makes the coating resistant to scratches, indentations, and abrasion. Further, the coatings of the present disclosure provide for enhanced light transmittance across the entire solar region from about 400 nm to about 1150 nm, which is desirable for solar applications.

Further, it should be appreciated that the sols resulting from the coating compositions of this disclosure do not need to be applied to the solar panels during manufacturing and may be applied after manufacturing to avoid any interference with the solar panel manufacturing process. It is expected that the solar panel maker themselves may be able to use the composition of this disclosure to coat the modules at appropriate points within their manufacturing process. In such instances, the provision of a stable sol, that can be used according to the methods described herein, provides a direct means for the applying the coating mixture after manufacture of the panels or even after final installation of the panels. This may streamline the manufacturing process and enhance the economic value of existing panels, either existing inventory or panels already installed and in use, to which the coatings can be applied.

Coating mixtures that can be used specifically for coating solar panels include (1) 0.71 tetraethoxysilane, 0.32% methyl trimethoxysilane, 0.32% trifluoropropyl trimethoxysilane, 0.018% HCl, 5.2% water, and 93.4% isopropanol; (2) 0.71% tetraethoxysilane, 0.32% methyl trimethoxysilane, 0.32% trifluoropropyl trimethoxysilane, 1.58% NH4OH, 3.68% water, and 93.4% isopropanol; and (3) 2.99% tetraethoxysilane, 0.018% HCl, 0.018% water, and 93.40% isopropanol, where all percentages are volume percents.

### EXAMPLES

The following describes various aspects of the coatings made according to certain embodiments of the disclosure in connection with the Figures. These examples should not be viewed as limiting.

In one embodiment referred to as Example 1, Sol I was prepared by first mixing 22.5 mL of isopropanol (IPA) and 2.5 mL of 0.04M HCl (pH 1.5). 100 μL of methyltrimethoxysilane (MTMOS) was then added to this mixture. The final solution of IPA, HCl, and MTMOS was then sonicated in a sonicator for 35 minutes. Sol II was prepared by first mixing 22.5 mL of IPA and 2.5 mL of 0.04M HCl (pH 1.5) followed by adding 100 μL of (3,3,3-trifluoropropyl)-trimethoxysilane (F3TMOS). Sol II was also sonicated for 35 minutes. After sonication, Sol I and Sol II was mixed in equal parts (12.5 mL each), and 100 μL of tetramethoxysilane (TMOS) was added. This final solution was then sonicated for 35 minutes. This mixture was allowed to age under ambient conditions for 24 hours up to 120 hours. After aging, microscope slides (polished with cerium oxide polish, washed, and allowed to dry) were flow coated with the final sol mixture and allowed to dry for approximately 5-10 minutes. Once dry, the slides were cured in one of two ways. In one method, the slides were placed coated side up on a hot plate/stirrer for 60 minutes at 120 degrees Celsius. The temperature was then cooled to 25 degrees Celsius at a constant rate over a period of 60 minutes.

In another embodiment referred to as Example 2, Sol 1 was prepared by first mixing 22.5 ml isopropanol (IPA) and 2.5 mL of 0.04 MHCl (pH 1.5). 300 μL of methyltrimethoxysilane (MTMOS) was then added to this mixture. The final solution of IPA, HCl, and MTMOS was then sonicated in a sonicator for 35 minutes. Sol II was prepared by first mixing 22.5 mL of IPA and 2.5 mL of 0.04M HCl (pH 1.5) followed by adding 300 μL of (3,3,3-trifluoropropyl)-trimethoxysilane (F3TMOS). Sol II was also sonicated for 35 minutes. After sonication, Sol I and Sol II was mixed in equal parts (12.5 mL each), and 675 μL of tetraethoxysilane (TEOS) was added. This final solution was then sonicated for 35 minutes. This mixture was allowed to age under ambient conditions for 24 hours up to 120 hours. After aging, microscope slides (polished with cerium oxide polish, washed, and allowed to dry) were flow coated with the final sol mixture and allowed to dry for approximately 1-10 minutes.

TEM cross-section of a representative sample of the dried and cured film from example 2 is shown in FIG. 3a. TEM cross-section and the High Resolution TEM of the film from example 2 show no evidence of long range order within the film. The film morphology at a scale 5 nm show little evidence of porosity.

In another embodiment referred to as Example 2.1 100 ml of above mixture is diluted with 88 ml of 99.9% pure isopropyl alcohol to enable coating on a 30 cm×30 cm substrate. SEM cross-section of a representative sample of the dried and cured film from example 2.1 is shown in FIG. 4.

In yet another embodiment referred to as Example 3, Sol 1 was prepared by first mixing 22.5 ml isopropanol (IPA) and 2.5 mL of 0.04 MHCl (pH 1.5). 262.5 μL of methyltrimethoxysilane (MTMOS) was then added to this mixture. The final solution of IPA, HCl, and MTMOS was then sonicated in a sonicator for 35 minutes. Sol II was prepared by first mixing 22.5 mL of IPA and 2.5 mL of 0.04M HCl (pH 1.5) followed by adding 262.5 iut of methyltrimethoxysilane (MTMOS). Sol II was also sonicated for 35 minutes. After sonication, Sol I and Sol II was mixed in equal parts (12.5 mL each), and 675 μL of tetraethoxysilane (TEOS) was added. This final solution was then sonicated for 35 minutes. This mixture was allowed to age under ambient conditions for 24 hours up to 120 hours. After aging, microscope slides (polished with cerium oxide polish, washed, and allowed to dry) were flow coated with the final sol mixture and allowed to dry for approximately 1-10 minutes. SEM cross-section of a representative sample of the dried and cured film from example 3 is shown in FIG. 5

In yet another embodiment referred to as Example 4, Sol 1 was prepared by first mixing 22.5 ml isopropanol (IPA) and 2.5 mL of 0.04 MHCl (pH 1.5). 425 μL of methyltrimethoxysilane (MTMOS) was then added to this mixture. The final solution of IPA, HCl, and MTMOS was then sonicated in a sonicator for 35 minutes. Sol II was prepared by first mixing 22.5 mL of IPA and 2.5 mL of 0.04M HCl (pH 1.5) followed by adding 150 μL of (3,3,3-trifluoropropyl)-trimethoxysilane (F3TMOS). Sol II was also sonicated for 35 minutes. After sonication, Sol I and Sol II was mixed in equal parts (12.5 mL each), and 662 μL of tetraethoxysilane (TEOS) was added. This final solution was then sonicated for 35 minutes. This mixture was allowed to age under ambient conditions for 24 hours up to 120 hours. After aging, microscope slides (polished with cerium oxide polish, washed, and allowed to dry) were flow coated with the final sol mixture and allowed to dry for approximately 1-10 minutes. SEM cross-section of a representative sample of the dried and cured film from example 4 is shown in FIG. 6.

Where applicable, the measurement of anti-reflective properties of the coatings was done as follows: The transmittance of the coatings was measured by means of UV-vis absorption spectrophotometer equipped with an integrator accessory. The anti-reflective enhancement factor is measured as the relative percent increase in transmittance compared to untreated glass slides versus glass slides coated with compositions of this disclosure. ASTM E424 describes the solar transmission gain, which is defined as the relative percent difference in transmission of solar radiation before and after the application of the coating. The coatings exhibit about 1.5% to about 3.25% gain in solar transmission. The refractive index of the coating was measured by an ellipsometer.

The abrasion resistance of the coating is measured by an abrader device according to European standard EN-1096-2 (glass in building coated glass). The coatings made according to Examples 1, 2, 3, and 4 without any added composition modifying additives, are able meet the passing criteria of the standard. Coatings made from Example 3 are exceptional in that it is able to have almost no damage after 500 cycles of testing per the EN-1096 standard. Abrasion losses are only 0.1%.

The contact angle of the coatings is measured by means of goniometer wherein the contact angle of the water droplet is measured by means of a CCD camera. An average of three measurements is used for each sample. On tin-sided float glass, average contact angles for coatings made from Example 2.1 measure 85° and on tin-sided TCO glass, average contact angles measure 90°.

The reliability results of the coatings in this disclosure are broadly similar to existing anti-reflective coatings. However, under 85° C./85% RH test conditions per IEC61215 and IEC61646 the coatings of this disclosure has a protective effect on glass corrosion which is not observed when highly porous anti-reflective sol-gel coatings are tested under similar conditions. Without being bound to theory, we believe that porous anti-reflective coatings facilitate easy leaching of sodium ions from the glass whereas the coatings of this disclosure can be tuned to achieve hydrophobic properties which slow down the rate and/or decrease the amount of water that is contact with the glass. Coatings made from examples of this disclosure exhibit minimal glass corrosion compared to uncoated glass. The other remarkable feature of the passing reliability results is that these reliability results have been achieved with a coating cured at just 120° C. Existing anti-reflective coatings are typically sintered at 400˜600 degrees centigrade to achieve the level of reliability indicated by these results.

FIG. 1 illustrates the UV-vis transmittance spectra showing maximum transmittance enhancement of 2.6% on with coatings on tin side of float glass from composition given in Example 2.1 compared to a maximum transmittance enhancement of 1.9%. A statistical comparison of 11 samples from coating made from composition in Example 2.1 on tin side vs non-tin side of float glass provided a solar weighted photon gain of 2.23% vs 1.93%. Without being bound to theory, the coatings of this disclosure interact with the tin side of float glass to provide an enhancement in the beneficial properties of the antireflective coatings.

FIG. 2 illustrates the UV-vis transmittance spectra comparing the different coatings from this disclosure to each other and to TCO coated glass. Coatings made from example 2.1, 3 and 4 of the disclosure were coated on the tin side of TCO coated glass and showed an improvement in solar weighted photon gain of 3.24, 2.01 and 2.57 respectively. Sols from the three formulations could have different inherent viscosities and it would be preferable to be able to tune the viscosities of the sols such that their solar weighted photon gain is maximized.

FIG. 3a is a TEM cross-sectional view of a coating made from the composition of Example 2 on a glass slide substrate. The TEM images show the absence of any discernible porosity in these coatings. The film thickness about 70-80 nm.

FIG. 3b is a HRTEM of a coating made from the composition of Example 2 on a glass slide.

FIG. 4 is an SEM cross-sectional view of a coating made from the composition of Example 2.1 on a 30 cm×30 cm float glass substrate. The SEM images show the absence of porosity and a film thickness of 133 nm.

FIG. 5 is an SEM cross-sectional view of a coating made from the composition of Example 3 on a 30 cm×30 cm float glass substrate. The SEM images show the absence of porosity and a film thickness of ˜83 nm.

FIG. 6 is an SEM cross-sectional view of a coating made from the composition of Example 4 on a 30 cm×30 cm float glass substrate. The SEM images show the absence of porosity and a film thickness of 76 nm.

The anti-soiling and self-cleaning property of coatings of this disclosure can be tuned by changing the surface characteristics of these coatings. XPS data for example coatings of this disclosure show how the fluorine content of the coatings can be varied from 0-9.1% and carbon content can be varied from 16.8% to 41.7%.

TABLE 5
Showing XPS Data for Coatings of this Disclosure
on Tin Side of TCO Coated Glass Subject
to 20 sec sputter to remove any adventitious impurities

| Sample | F % | C % | Si % | O % | N % | Na % | Ca % |
|---|---|---|---|---|---|---|---|
| Example 2.1 + 20 sec | 9.1 | 41.7 | 16.1 | 32.1 | nd | 0.6 | 0.4 |
| sputter | | | | | | | |
| Example 3 + 20 sec | nd | 16.8 | 28.5 | 53.6 | nd | 0.7 | 0.3 |
| sputter | | | | | | | |
| Example 4 + 20 sec | 7.4 | 25.3 | 21.7 | 44.1 | 0.5 | 1.0 | nd |
| sputter | | | | | | | |

TABLE 6
Showing XPS Data for Coatings of this Disclosure
in the native state and after 10 minutes of
Argon Sputter Etch on Tin Side of TCO coated Glass

| Sample | F % | C % | Si % | O % | Sn % | Na % | Ca % |
|---|---|---|---|---|---|---|---|
| Example 2.1 as | 11.9 | 39.5 | 14.9 | 32.7 | nd | 0.6 | 0.4 |
| received | | | | | | | |
| Example 2.1 after | 12.9 | 13.1 | 28.7 | 45.1 | 0.2 | Nd | nd |
| 10 min sputter | | | | | | | |

A comparison of the XPS data for the as received sample from Example 2.1 and the XPS data for the same sample after it was sputtered with Argon ions for 10 minutes show that Fluorine from the coating material is present in the as received sample and after the minute etch. The data also shows that small amount of tin from the tin side of the TCO coated float glass are detected along with the coating.

Various embodiments of the disclosure have been described above. However, it should be appreciated that alternative embodiments are possible and that the disclosure is not limited to the specific embodiments described above. Rather, the description of these embodiments should be considered exemplary of various embodiments that fall within the scope of the present disclosure as defined by the claims.

What is claimed is:

1. A coated glass element adapted for use in a solar module, comprising:
a solar glass component; and
a coating adhered to the solar glass component through siloxane linkages, the coating having abrasion resistance and at least one of an anti-reflective property and an anti-soiling property;
wherein the coating comprises a dried gel formed from a combination of sols comprising:
a hydrolyzed organosilane-based sol; and
a hydrolyzed tetraalkoxysilane-based sol, wherein the tetraalkoxysilane is selected from the group consisting of tetraethoxysilane (TEOS) and tetramethoxysilane (TMOS).

2. The element of claim 1, wherein the solar glass component comprises at least one of float glass, rolled glass, glass lenses, and mirrors.

3. The element of claim 1, wherein the solar glass component is tempered.

4. The element of claim 1, wherein the solar glass component is untempered.

5. The element of claim 1, wherein the dried gel has abrasion resistance sufficient to pass standard EN-1096-2 with an absolute loss of transmission of no more than 0.5% and enables a post-test light transmission gain of greater than 1% on an absolute basis as compared to uncoated glass when cured at less than 300° C.

6. The element of claim 1, wherein the dried gel has no observable porosity.

7. The element of claim 1, wherein the organosilane comprises methyltrimethoxysilane (MTMOS).

8. The element of claim 1, wherein the coating has a contact angle of about 70 degrees to about 178 degrees and resists chemical and physical interactions.

9. The element of claim 1, wherein the coating has a hardness of greater than 2 GPa.

10. The element of claim 1, wherein the coated solar glass component has an
increased transmission of about 1% to about 3.5% on an absolute basis compared to an uncoated solar glass component and the coating further has an anti-soiling property.

11. The element of claim 1, wherein the solar glass component is selected from the group consisting of a crystalline silicon solar glass, an amorphous silicon solar glass, a Cd—Te solar glass, and a CIGS solar glass.

12. The element of claim 1, wherein a molecular weight of the sol is less than 1000.

13. The element of claim 1, wherein the hydrolyzed sols remain stable for a significant period of time without exhibiting change in its chemical or physical characteristics such that when applied to the solar glass component and cured at a temperature of less than 300° C., the dried gel has abrasion resistance sufficient to pass standard EN-1096-2 with a loss of transmission of no more than 0.5% and enables a post-test light transmission gain of greater than 1% as compared to an uncoated solar glass component.

14. The element of claim 1, wherein the coating has an anti-reflective property and a thickness of the coating is adapted to enhance solar transmission between 300 nanometers and 1150 nanometers.

15. The element of claim 1, wherein the coating has an anti-reflective property and a thickness of the coating is selected to provide enhanced transmission for a selected type of solar module assembly.

16. The element of claim 1, wherein the coating provides a corrosion mitigating effect on the solar glass component when tested under 85° C./85% RH test conditions per at least one of IEC61215 and IEC61646.

17. An abrasion-resistant, anti-reflective coating for glass, comprising:
a dried gel formed from a combination of sols comprising:
a hydrolyzed organosilane-based sol; and
a hydrolyzed alkoxysilane-based sol, wherein the alkoxysilane is selected from the group consisting of tetraethoxysilane (TEOS) and tetramethoxysilane (TMOS);
wherein when applied to glass and cured at a temperature of less than 300° C., the dried gel has abrasion resistance sufficient to pass standard EN-1096-2 with an absolute loss of transmission of no more than 0.5% and enables a post-test light transmission gain of greater than 1% on an absolute basis as compared to uncoated glass.

18. The coating of claim 17, wherein the dried gel has no observable porosity.

19. The coating of claim 17, wherein the coating has a contact angle of about 70 degrees to about 178 degrees and resists chemical and physical interactions.

20. The coating of claim 17, wherein the organosilane comprises methyltrimethoxysilane (MTMOS).

21. The coating of claim 17, wherein the coating has a hardness of greater than 2 GPa.

22. The coating of claim 17, wherein the temperature is selected to tune the abrasion resistance of the coating.

23. The coating of claim 17, wherein a ratio of hydrolyzed organosilane-based sol to hydrolyzed alkoxysilane-based sol is selected to tune the abrasion resistance of the coating.

24. The coating of claim 17, wherein the organosilane and the alkoxysilane are selected to tune the abrasion resistance of the coating.

25. The coating of claim 17, wherein a molecular weight of the sol is less than 1000.

26. The coating of claim 17, wherein the hydrolyzed sols remain stable for a significant period of time without exhibiting change in its chemical or physical characteristics such that when applied to the glass and cured at a temperature of less than 300° C., the dried gel has abrasion resistance sufficient to pass standard EN-1096-2 with a loss of transmission of no more than 0.5% and enables a post-test light transmission gain of greater than 1% as compared to an uncoated glass.

27. The coating of claim 17, wherein a thickness of the coating is adapted to enhance light transmission between 300 nanometers and 1150 nanometers.

28. The coating of claim 17, wherein the coating provides a corrosion mitigating effect on the glass when tested under 85° C./85% RH test conditions per at least one of IEC61215 and IEC61646.

29. An abrasion-resistant, anti-reflective coating applied to glass, wherein the coating exhibits:
no observable porosity;
an absolute reduction in reflection of about 1.0% to about 3.5% as compared to uncoated glass;
a hardness of greater than about 1.5 GPa;
a thickness of about 80 nm to about 140 nm; and
sufficient toughness and adhesion to the glass to pass standard EN-1096-2 with an absolute change in reflection of no more than 0.5% as measured after about 2,000 abrasion strokes.

30. The coating of claim 29, wherein the glass is a component of a solar module and wherein the coating improves the peak power output of the solar module by about 1.0% to about 3.5% on a relative basis.
